(19) United States
(12) Patent Application Publication
(10) Pub. No.: US 2007/0170437 A1
(43) Pub. Date: Jul. 26, 2007

(54) Hierarchical Assembly of Interconnects for Molecular Electronics

(75) Inventors: Gregory N. Parsons, Raleigh, NC (US); Daniel L. Feldheim, Cary, NC (US); Christopher B. Gorman, Cary, NC (US)

Correspondence Address: MYERS BIGEL SIBLEY & SAJOVEC, PO BOX 37428, RALEIGH, NC, 27627, US

(73) Assignee: North Carolina State University

(21) Appl. No.: 11/558,180

(22) Filed: Nov. 9, 2006

Related U.S. Application Data
(63) Continuation of application No. 10/894,152, filed on Jul. 19, 2004, now abandoned.
(60) Provisional application No. 60/489,009, filed on Jul. 21, 2003.

(51) Int. Cl. H01L 31/0312

(52) U.S. Cl. 257/77

(57) ABSTRACT

A hierarchical assembly methodology can interconnect individual two- and/or three-terminal molecules with other nanoelements (nanoparticles, nanowires, etc.) to form solution-based suspensions of nanoscale assemblies. The nanoassemblies can then undergo chemical-selective alignment and attachment to nanopatterned silicon and/or other surfaces for interconnection and/or measurement.

### CROSS-REFERENCE TO RELATED APPLICATIONS

This application is a continuation of application Ser. No. 10/894,152, filed Jul. 19, 2004, entitled Hierarchical Assembly of Interconnects for Molecular Electronics, and claims the benefit of provisional Application No. 60/489,009, filed Jul. 21, 2003, entitled Hierarchical Assembly of Interconnects for Molecular Electronics, the disclosures of which are hereby incorporated herein by reference in their entirety as if set forth fully herein.

### FIELD OF THE INVENTION

This invention relates to microelectronic devices and fabrication methods therefor, and more particular to nanotechnology devices and fabrication methods therefor.

### BACKGROUND OF THE INVENTION

While silicon technology continues to extend into regimes that may have been previously thought to be difficult or even impossible, the field of molecular-based electronic materials and devices is beginning to gain interest as a potential future challenge or extension to silicon. Recent news that molecular systems can be used to achieve current gain^{1,2} may heighten interest. Demonstration of gain in a molecular electronic system may open new possibilities for ultra-small logic and memory systems, but broad new sets of challenges in materials understanding may need to be addressed. For example, there may be challenges in contact and charge transport in nanoscale electronic molecules. These challenges may define the emerging cross discipline field of Nanoscale Electronics to include issues in molecular synthesis, development of new strategies for assembly at multiple length scales, and characterization of nanometer-scale components in an operational environment. Research and education in this area may help expand this field for future technology and science.

### SUMMARY

Some embodiments of the invention provide 3-terminal molecular electronic devices. Other embodiments of the present invention provide synthesis of new molecules with functionality that allows them to act as nonlinear electronic elements and to chemically attach to silicon-based contact structures. Still other embodiments of the invention provide construction of a nanoparticle-based assembly that can bridge molecular and lithographic length scales. Yet other embodiments of the present invention provide definition of new lithographic approaches that can accommodate molecular installation during processing.

Some embodiments of the invention provide a hierarchical assembly methodology to interconnect individual two- and/or three-terminal molecules with other nanoelements (nanoparticles, nanowires, etc.) to form solution-based suspensions of nanoscale assemblies. The nanoassemblies can then undergo chemical-selective alignment and attachment to nanopatterned silicon and/or other surfaces for interconnection and/or measurement. Measurements can focus on characterization of the nanoscale elements self-assembled within the lithographically defined features and/or mapping out of molecular structure property relationships that may govern molecular electronics behaviors. Both of these characterizations may expand the understanding of molecular electronic materials for future device operation.

It is known that transistor behavior can be exhibited in single molecules.^{3,4} These results illustrated the concept of gain, and correlated current-voltage behavior with other properties of the molecule (e.g., a change in spin state). However, embodiments of the present invention can provide gain as the result of a state change within the molecular architecture rather than as the response of a molecule to a change in bias of an underlying (macroscopic) gate electrode. Moreover, an open architecture of some embodiments of the invention can facilitate spectroscopic characterization in addition to correlation of current-voltage behaviors with molecular properties. Finally, embodiments of the invention can bridge the lithographic and molecular length scales by room temperature, orthogonal self-assembly. This strategy can offer the possibility of larger scale integration, rather than making devices in a sequential (one at a time) fashion.

### BRIEF DESCRIPTION OF THE DRAWINGS

FIG. 1 illustrates examples of geometrically well-defined particle arrangements according to some embodiments of the present invention.

FIG. 2 graphically illustrates an SER spectrum of a particle dimer according to some embodiments of the present invention.

FIG. 3 is a schematic for nanoparticle heterotrimer synthesis according to some embodiments of the present invention.

FIG. 4 illustrates thiols binding selectively to gold and isonitriles binding selectively to platinum according to some embodiments of the present invention.

FIG. 5 schematically illustrates two strategies for preparation of a gate according to some embodiments of the present invention.

FIG. 6 illustrates redox units that can be exploited according to some embodiments of the present invention.

FIG. 7 is a cross-sectional view of a thin film transistor device fabricated with conventional lithography and a modification thereto using nanopatterning techniques according to some embodiments of the present invention.

FIG. 8 illustrates a detailed process schematic for fabrication of nanometer scale trenches according to some embodiments of the present invention

FIG. 9 schematically illustrates the use of AFM nanolithography to prepare an electronic test bed according to some embodiments of the present invention.

FIG. 10 is a schematic diagram of a molecular test device structure according to some embodiments of the present invention.

FIG. 11 is a schematic diagram showing incorporation of a nanoparticle heterodimer into a trench structure according to some embodiments of the present invention.

FIG. 12 is a schematic diagram of a vertically-patterned test structure according to some embodiments of the present invention.

FIG. 13 graphically illustrates NMR spectra according to some embodiments of the present invention.

FIG. 14 illustrates an electrostatic field associated with a three terminal moltronic device according to some embodiments of the present invention.

FIG. 15 schematically illustrates hierarchical assembly contact schemes according to some embodiments of the present invention.

FIG. 16 schematically illustrates a prototype three terminal nanodevice according to some embodiments of the present invention.

FIG. 17 illustrates redox-level matching and gate arms according to some embodiments of the present invention.

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the sizes and relative sizes of layers and regions may be exaggerated for clarity.

Some embodiments of the invention can provide self-assembly methods that can bridge two- and/or three-terminal molecules to electrodes. Gain may be demonstrated at the molecular level using a three-terminal molecular wiring scheme. Gain has been demonstrated using gate electrodes placed under or beside collections of two-armed molecules. Although the electronic properties of such architectures can provide gain, such arrangements may not be scalable to the molecular level. Other, three-armed molecules have been made⁵ or proposed^{6,7} but they may not differentiate the low impedance (source-drain) and high impedance (source-gate) pathways that exist in a molecular-based field effect transistor. They may also not describe how to bridge the length scales between lithography (about 100 nm) and molecules (about 5 nm).

Nanoparticle interconnect strategies according to some embodiments of the invention may provide various advantages. First, molecules are small and thus may be difficult to address electronically. Embodiments of the invention may achieve electrical contact on a molecular level. Some evidence exists that electrical contacts may have been made to two-terminal molecules. However, addressing 3-terminal molecular Field Effect Transistors (molFETs) may need to place three opposing metallic leads within about 10 nm. Patterning electrodes with such extraordinary fidelity may currently be difficult or impossible, even with state-of-the-art electron beam lithography. Attaching metal nanoparticles to a molFET first in solution, according to some embodiments of the present invention, can obviate the need for ultra-high resolution wafer patterning techniques. For example, if 30 nm diameter metal nanoparticles are attached to each of the three apices of a molFET, the distance between electrical contacts on the wafer increases to about 50 nm, a length scale that can be reached using electron beam lithography and/or other nanopatterning approaches.

A possible second advantage of nanoparticle interconnects according to some embodiments of the present invention is that they may facilitate the integration of individual molecular device components to form circuits, without the need to alter the electrical characteristics of those components in the process. That is, if one were to covalently attach a molecular diode to a molFET, the desired electrical properties of the diode and molFET may likely change (e.g., turn-on voltage, conductivity, etc.). (When molecules react, their electronic properties may change.) However, if the molecular diode were integrated with the molFET via a metal nanoparticle interconnect, their device characteristics may be less likely to be affected.

Finally, connecting molecules to nanoparticle interconnects prior to their assembly into an electrical circuit, according to some embodiments of the present invention, can enable the characterization of basic structural parameters such as the number of molecules contacted and the identity of the contact chemistry. In 2-terminal molecular electronic demonstrations presented to date, the molecular identity, number of molecules addressed, and the contact chemistry may not have been clearly characterized. The nanoparticle/molFET hybrids described here may be amenable to standard solution-phase molecular characterization techniques such as NMR and Raman spectroscopy. Thus, molecular level information that is the hallmark of chemistry can be obtained prior to assembly on chip. Once assembled into a circuit, the number of molecules contacted can be quantified by finding their associated nanoparticle interconnects. Nanoparticles are dense and may be easily identified by AFM, STM and/or field-emission scanning electron microscopy.

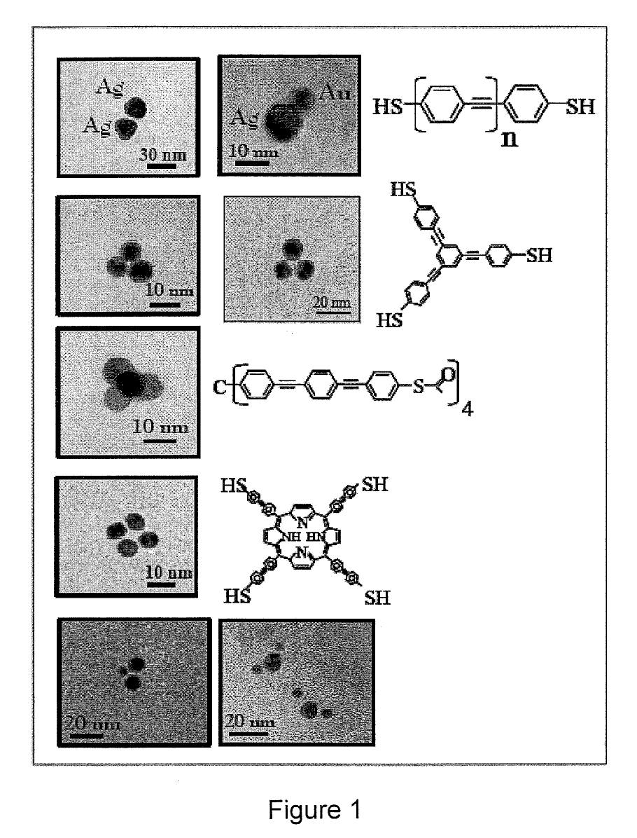

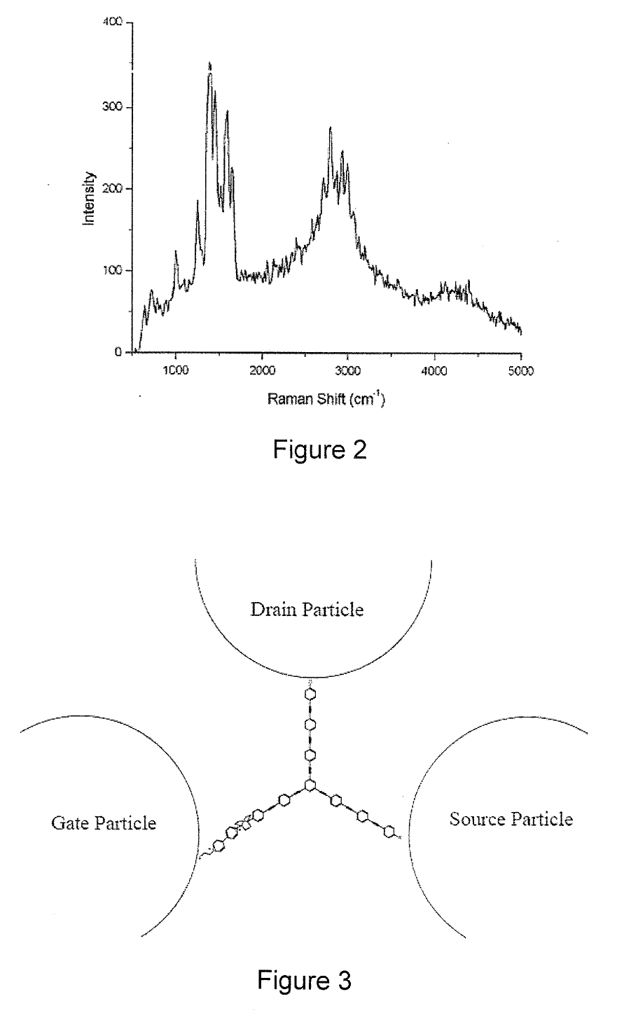

The assembly of phenylacetylene- and DNA-linked metal particle (5 nm diameter silver, gold) dimers, trimers, and tetramers with D_{∞h}, D₃ₕ, D₄ₕ, and T_{d} symmetries as shown in FIG. 1 has been described.⁸⁻¹² A particular emphasis in prior studies appears to have been placed upon (i) collecting highly enriched fractions of a desired nanoparticle array, (ii) characterizing array symmetry and interparticle distance by multiple methods, (iii) determining the number of molecular bridges between nanoparticles, and (iv) establishing symmetry and distance dependent electronic and electromagnetic interactions between particles. Array purity has been increased by centrifugation and size-exclusion chromatography.⁸ Transmission electron microscopy, visible spectroscopy,^{9,10} and hyper-Rayleigh scattering spectroscopy¹¹ have shown unambiguously that the symmetry and length of the chosen molecular bridge can dictate symmetry and interparticle distance in the resulting nanoparticle array. As shown in FIG. 2, polarized surface-enhanced Raman spectroscopy (SERS) of individual silver particle dimers has confirmed that a single phenylacetylene linker bridges the two nanoparticles.¹² Also, see United States Patent Application Publication No. US 2003/0067668 A1 to Feldheim et al., entitled Electronic Devices and Methods Using Arrays of Molecularly-Bridged Metal Nanoparticles, published Apr. 10, 2003.

Finally, visible spectroscopy, hyper-Rayleigh scattering spectroscopy, and differential pulse voltammetry have been used to characterize symmetry and distance dependent interparticle electronic communication. Strong coupling has been observed, with the predominant mechanism characterized to date as dipole coupling.

The prior work highlighted briefly above may suggest (i) stable solution suspensions of molecules attached to nanometer-sized metal particles can be obtained in purified form, (ii) solution suspensions of nanoparticle arrays can be characterized using the traditional spectroscopic tools used by chemists (NMR, visible, Raman, etc.), and (iii) individual nanoparticle arrays can be characterized by electron microscopy, scanning probe lithographies, and because metal nanoparticles provide enormous Raman enhancements, by single molecule SERS. In addition to the device applications described below, a hierarchical assembly approach according to some embodiments of the invention may give rise to new capabilities in separation and characterization of molecules. A nanoparticle attachment strategy according to some embodiments of the invention can enable individual molecules to be isolated, manipulated and characterized. An example is shown in FIGS. 1-2, where an individual phenylacetylene molecule bridging two 30 nm diameter silver nanoparticles has been positioned and characterized in a Raman spectrometer system.

As stated above, it may be desirable to bind at least one particle (the gate particle) to a different contact than the other particles (the source and drain particles). Embodiments of the invention can employ orthogonal self-assembly of binding groups on the different particles as detailed below. The concept of orthogonal self-assembly was illustrated by Wrighton,^{13,14} but does not appear to have been used to make a device. A first step in a device construction scheme can be the fabrication of nanoparticle heterotrimers (FIG. 3). These are related to the nanoparticle trimers previously reported¹⁰ but, in this case, not all of the particles may be the same. This synthesis can provide a platform to verify that orthogonal self-assembly is a viable construction strategy for these heterotrimers. This orthogonal self-assembly can then be employed again to install these heterotrimers correctly into a surface template.

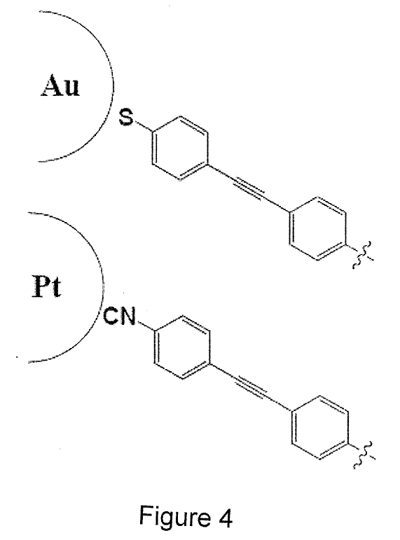

As shown in FIG. 3, in a nanoparticle heterotrimer, at least one particle (the gate particle) is different from the others. According to some embodiments of the invention, different particles and contact strategies can facilitate correct installation of the trimer into a trench via orthogonal self-assembly. For source and drain contacts, a thiol-terminated arm connects to a gold nanoparticle. Alternatively, an isonitrile-terminated arm could connect to a platinum nanoparticle (FIG. 4). Whichever arm-functionality/particle pair is employed, the opposite may be employed for the gate arm-functionality/particle. Mallouk et al.¹⁵ have shown that thiols and isonitriles can be used simultaneously in orthogonal self-assembly onto segmented nanorods. This orthogonal self-assembly can be extended to the formation of nanoparticle heterotrimers according to some embodiments of the present invention.

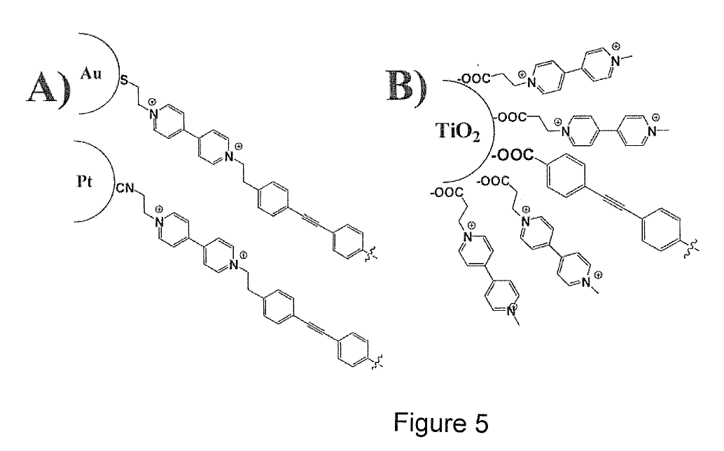

In some embodiments, the gate is functionalized with electroactive groups. The electroactive groups may be synthesized within the “gate” arm of the molecule joining the heterotrimer (FIG. 5A), or added separately to the “gate” nanoparticle (FIG. 5B). Then, applied gate voltage can switch these groups into different redox states with different charges. This change in electrostatic potential at the gate can be analogous to a voltage applied to a doped polysilicon gate electrode in a conventional FET, but at the molecular level. Although the first strategy (FIG. 5A) may better fit with the idealized concept of a single-molecule FET, the second strategy (FIG. 5B) may be pursued for at least three reasons. First, it can be more modular—it need not use a total synthesis to change the electroactive group. Thus, several different electroactive moieties can be studied—often using electroactive thiols, isonitrile, etc., already available from previous research. Second, this strategy can offer the ability to change the number of molecules comprising the gate. Thus, the behavior of the molFET can be studied systematically as more/fewer gating molecules are employed. Third, there may be an advantage to using “non-conducting” nanoparticles such as TiO₂ (FIG. 5B) to minimize leakage of the built up charge at the gate into the source-drain pathway.

Water-soluble TiO₂ nanoparticles may be synthesized using standard titanium isopropoxide hydrolysis chemistry. TiO₂ nanoparticles can be modified with a variety of small molecule ligands containing carboxylates or phosphonates. Based upon the vast TiO₂ literature,¹⁶⁻¹⁸ carboxylate ligands bound to TiO₂ may be susceptible to exchange. For example, the recent paper by Beek and Janssen¹⁹ indicates that monodisperse stearic-acid-coated titania particles can be synthesized and subsequently functionalized with terthiophene carboxylic acid via a process that presumably is analogous to ligand exchange. Ligand exchange is a property that may be used for the assembly of nanoparticles into the trimeric assemblies described herein. In order to better understand place exchange reactions of carboxylates and phosphonates on TiO₂ nanoparticles, exchange rates may be measured using fluorescence spectroscopy, and NMR spectroscopy (see below). These studies can determine exchange rates and equilibrium compositions for carboxylate and phosphonate substitutions in which short chains are replaced by long chains and vice versa. This information can be used to design new reaction schemes for assembling asymmetric molecularly bridged heterostructures.

In some embodiments, electroactive groups also may be incorporated directly into the molecular gate arm as shown in FIG. 5A. This approach can represent all the functions of a FET in a single molecule—so that it may be an embodiment of a single-molecule transistor. From a practical point of view, the second strategy (FIG. 5B) may provide a convenient route for systematic variation of the gate moiety. Thus, molecular structure-property relationships may be elucidated with this strategy (FIG. 5B). Based on these investigations, one candidate (e.g., choice of gate moiety) may be elaborated using the first strategy (FIG. 5A) for comparison.

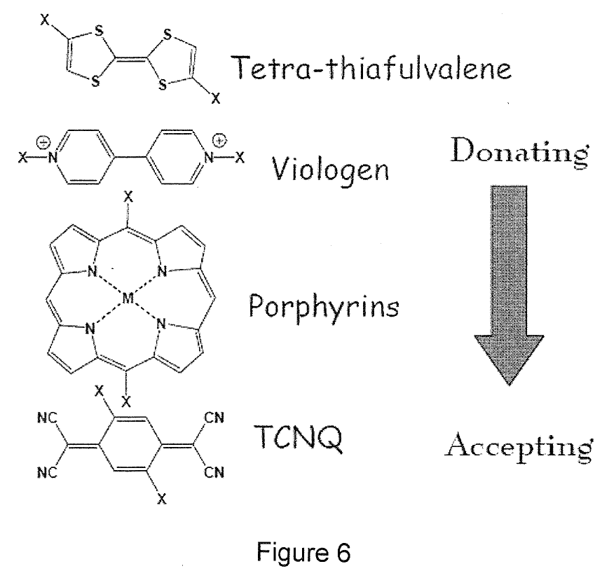

The synthesis of stiff-conjugated arms may take advantage of well-precedented chemistry. For example, phenyl ethynyl-based isocyanides²⁰ and thiols^{21,22} have been reported and these types of moieties have substantial precedent for binding to nanoparticles.^{9,10,15} An issue in molecular design may be relative redox potential of the electroactive gate group. However, as detailed in FIG. 6, chemistry for the functionalization of a variety of electroactive moieties (substitution at the positions marked with an X in each moiety below) is known.

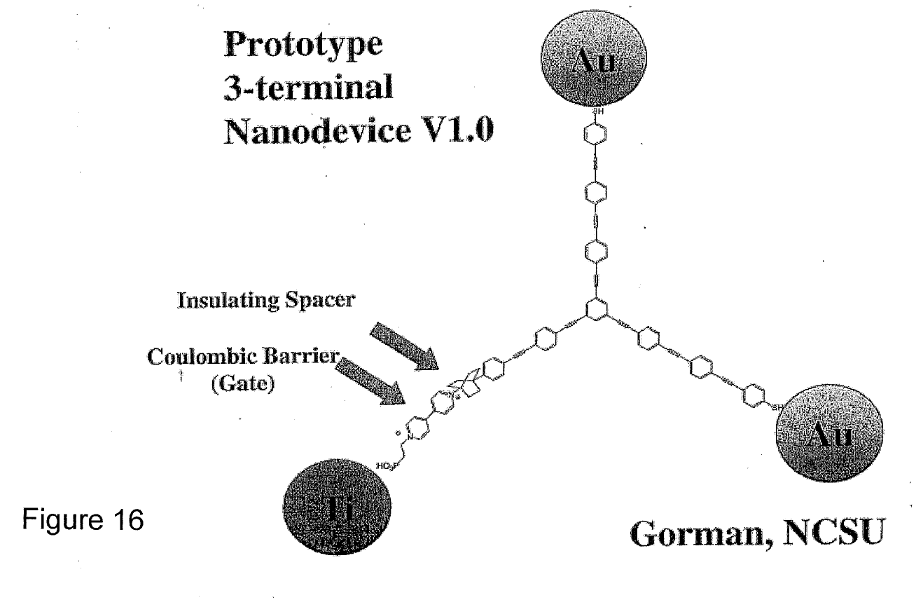

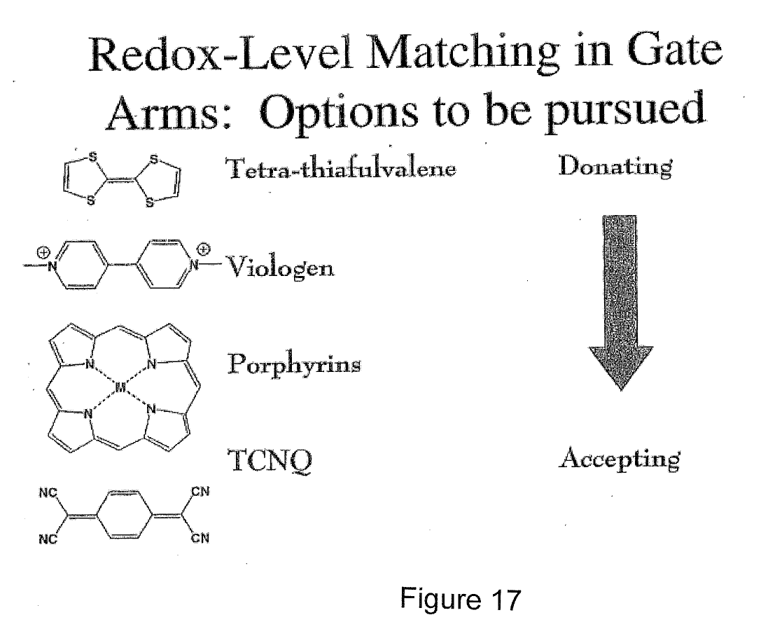

Accordingly, some embodiments of the present invention can provide a class of molecules with multiple input/output terminals that can be designed to: be wired selectively to particles and/or lithographically define contacts; possess different chemical functionalities at the different terminals so each terminal can act as either a source, drain or gate moiety, as defined for conventional semiconductor devices; and/or display, at the molecular level, memory, sensing, logic and/or gain functions. Examples of molecules are provided in FIG. 16. This molecule is designed to act as the molecular analog of a field effect transistor. The moiety at the illustrated “gate arm” can be any electro-active architecture that can be chemically oxidized or reduced at low applied potentials, and is separated from the source/drain pathway by the equivalent of an electrically insulating spacer at the molecular level. The electro-active architecture can be any chemical moiety which, upon oxidation or reduction, will perturb the magnitude of the source/drain current. Several possible implementations are shown in FIG. 17.

New engineering approaches and structures may be desired to isolate and characterize electronically active molecules. Some embodiments of the invention can fabricate micron- and submicron-scale structures that can enable demonstration of hierarchical assembly, to bridge the gap between micro- and nanoscale functional electronic elements. These embodiments can use a combination of conventional material deposition and lithography (for contact extensions and probe pads, for example) and/or advanced nanoscale patterning techniques. Pre-designed selective functionalization of multiple material surfaces within the nanostructure may also be performed to guide the hierarchical assembly. Some embodiments can design and demonstrate methodologies to assemble molecules into configurations compatible with chemical and electrical analysis, where potentially destructive processes, such as direct evaporation of metal onto molecules, may not be used.

Patterned silicon-based structures may be used to test schemes for orthogonal self-assembly, multi-step lithographic patterning and/or electrical characterization. Embodiments of the invention can take advantage of thin-film semiconductor device fabrication tools and expertise available²³. In some embodiments, nanoscale devices may be assembled as follows:

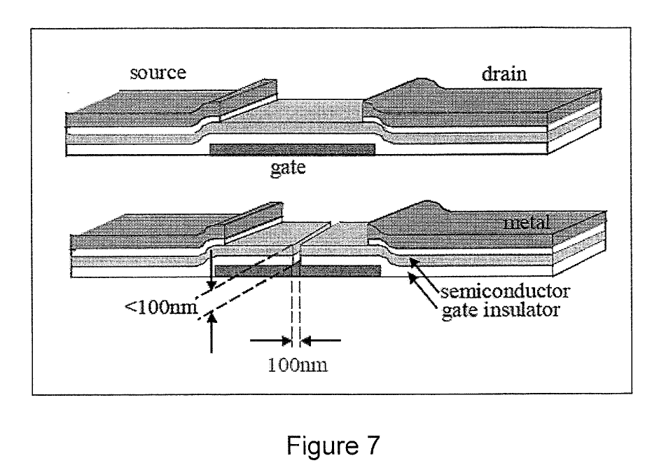

1. Fabricate and test functional thin-film amorphous or poly-silicon devices at the micron or submicron scale (top image, FIG. 7).

2. Use optical nanoscale lithography to fabricate “gaps” in the semiconductor thin film where large (100 nm) nanoparticle/molecule clusters can be assembled (bottom image, FIG. 7). This effort can utilize a new 193 nm optical lithography tool to be installed at NC State University's newly instituted Triangle National Nanolithography Center. This 193 nm lithography tool will be capable of sub 100 nm line and space definition, and may be the only 193 nm lithography tool in an academic institute in the U.S. Other advanced nanopatterning approaches, such as nanoimprinting, edge defined lithography, and/or atomic force lithography, may be used to form “gaps” in the sub-100 nm size range, to enable single molecule/nanoparticle clusters to be assembled onto the device and tested.

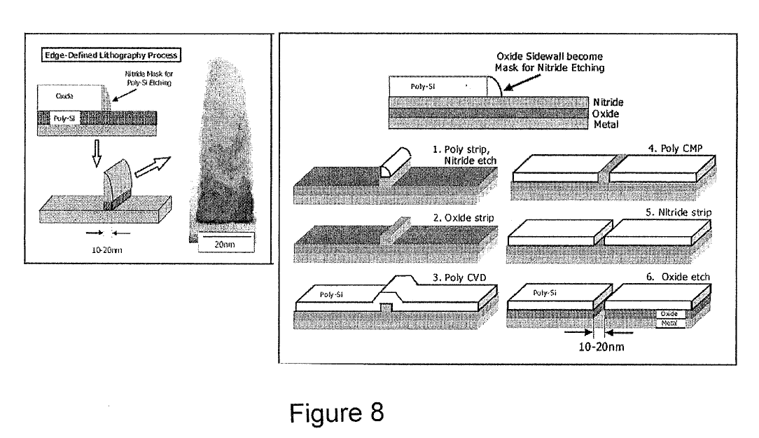

This scaling approach can allow testing of the scaling of the silicon-based structure itself, to better understand effect of scale on electronic measurement and results. For example, structures at the 200 nm scale (FIG. 7) can be tested with inert molecules in place (or no molecule at all) for leakage and parasitic capacitance, and results compared to similar structures fabricated at smaller dimensions (FIG. 8).

Several approaches for fabrication and patterning of advanced device structures can be provided according to embodiments of the present invention. Each is described in turn below. For film deposition, several well-characterized approaches may be available, including LPCVD and plasma enhanced CVD, and deposition thickness can be routinely controlled to within a few percent. As shown above, the width of the trench may be determined by lithography and dry (plasma) etching for dimensions in the 200 nm range. Plasma etch tools compatible with silicon and oxide etching are currently available. For sub 100 nm, alternate patterning approaches may be used, as discussed below.

In particular, achieving true molecular level characterization may use advanced patterning techniques beyond what is achievable with lithography alone. One example approach that allows structures to scale geometrically with the structures shown in FIG. 7, with the scale reduced by a factor of 10 or more, is outlined in FIG. 8. It involves an edge-defined lithography process, where a step is formed using conventional lithography, and an oxide or nitride film is deposited over the step and anisotropically etched to form a “sidewall” structure. Formation of sidewall structures such as this are routinely done in IC manufacturing, and sidewall “lines” in the 10-20 nm range, such as the one shown in FIG. 8, have been demonstrated many times. Extending the sidewall line fabrication to trench structures may use additional process steps, as shown in FIG. 8. The steps may involve forming a 10-20 nm line, depositing a conformal poly-silicon layer by CVD or PECVD (Step 3, FIG. 8), planarizing the poly-Si using chemical mechanical planarization, then removing the sacrificial nitride spacer, and dry-etching the oxide using the poly-Si as a mask. These steps do not appear to be fundamentally limiting in terms of materials or process definition.

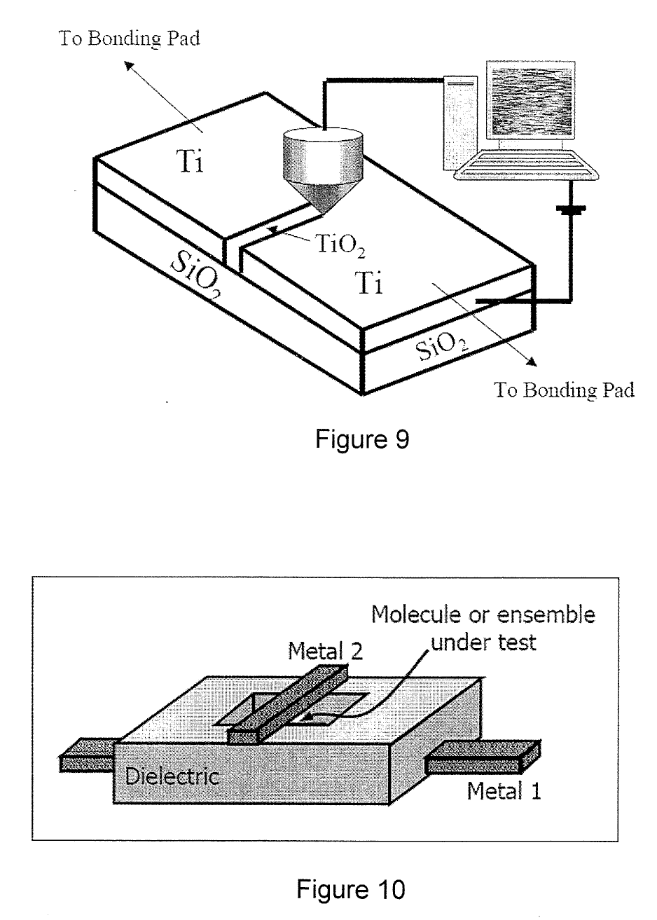

Atomic Force Microscope (AFM) lithography is another possible method for fabricating sub-100 nm trench structures for nanoparticle/molecule alignment and analysis. This approach is shown in FIG. 9. The method has been coined “AFM nanooxidation” by others, because an electrochemical AFM tip is used to create a gap of insulating TiO₂₍ₛ₎ between two conductive Ti₍ₛ₎ lines (FIG. 9). The insulating gap can be made on the order of 10 nm, well within the dimensions used for contacting molecularly bridged gold particle dimers.

Scanning probe methods currently may be too slow to fabricate large-scale integrated circuitry. However, AFM nanooxidation may enable fundamental electron transport measurements in the short term, while edge-defined lithography is coming online. In the long term AFM nanooxidation may be used as a quick, inexpensive way to screen molecules for desired electrical characteristics prior to assembly in the more sophisticated circuit architectures fabricated with edge-defined lithography.

Another silicon-based nanostructure that can be formed at various length scales for molecular analysis is shown in FIG. 10. For this device, two metal (and/or polysilicon) lines are formed across each other, and a dielectric layer is etched out between the lines forming a gap in which a molecular/nanoparticle construct can be aligned. Similar to the structure detailed above, the device can be formed with lines in the 200 nm range using conventional lithography tools, then scaled to 10-20 nm lines using edge-defined or other advanced patterning approaches.

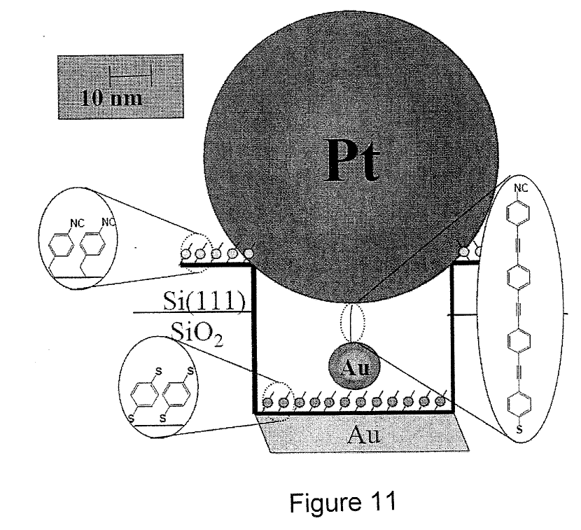

A structure that can be used to characterize single molecule elements, according to some embodiments of the invention, is shown in FIG. 11 in a scaled schematic. In this structure, a nanoparticle/molecule hetero-dimer is allowed to self-assemble into a functionalized silicon-based structure. The nanoparticle hetero-dimer is made with one relatively large and one smaller nanoparticle, with a well defined molecular connector between them. The silicon-based structure can be made in a “hole” or “trench” configuration, and may involve deposition of three layers: bottom (or floor) conductor, insulator, and top (or opening) conductor. For the example shown, the bottom conductor is PVD gold (prepatterned to make external bottom contact), and an about 80 nm thick layer of SiO₂, followed by an about 20 nm thick layer of heavily doped polycrystalline silicon are deposited on top. The doped poly will be patterned separately to form top external contact. External contacts may be made as shown in FIG. 7.

For initial measurements, relatively large nanoparticles (˜150 nm) may enable trench or hole widths in the 100 nm range to be used. Controlling the deposited film thickness may enable excellent control over trench or hole geometry, even including possible statistical variability in feature width. The nanoparticle/molecule hetero-dimer structure shown in FIG. 11 can be insensitive to statistical fluctuations, within a fairly wide range of feature widths. The structure can be resistant to variations because the difference in nanoparticle size can allow variability in the molecule alignment angle, while still allowing electrical contact between the nanoparticles and the top and bottom external contacts. As shown in FIG. 11, the top poly and bottom gold contact layers are selectively functionalized to promote selective attachment of the platinum and gold nanoparticles, respectively. The approach for the selective functionalization according to some embodiments of the invention may involve a four-step procedure: Standard surface characterization by IR and XPS may be pursued after each step to verify the efficacy of each functionalization step.
1. Prepare a trench with gold bottom and H-terminated silicon top using the schematic illustrated in FIG. 11. To hydrogen-terminate the silicon, a brief HF dip may be performed. This treatment, if brief, may not significantly roughen the gold.
2. Expose to alkene-terminated isonitrile to functionalize poly-silicon (predominantly Si(111)) using hydrosilation chemistry described in the literature.²⁴⁻²⁸ Hydrosilation chemistry may not react with the gold in the bottom of the trench, and any contamination may easily be displaced by the thiol in the next step.
3. Expose to thiol-terminated thiol to functionalize Au.
4. Expose functionalized trench to a solution containing Pt—Au nanoparticle dimers. The chemistry as well as the geometric constraints (the large Pt colloid should be too big to fit in the hole), can direct the assembly as shown in FIG. 11.

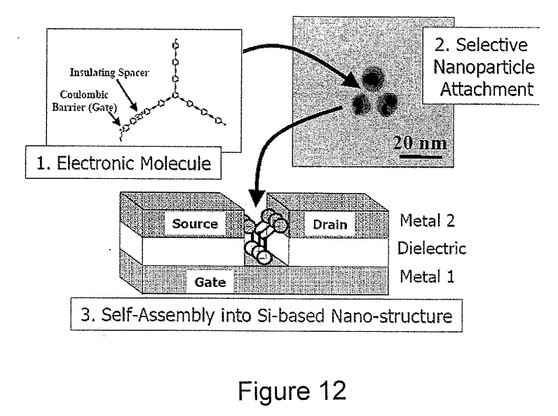

An extension of the structure described in FIG. 11 is a trench structure, according to other embodiments of the present invention, shown in FIG. 12, where a nanoparticle/molecule hetero-trimer is assembled into a three-terminal analysis configuration. The structure of FIG. 12 shows two metals, however, a variety of top and bottom contact materials and configurations could be envisioned. The approach for surface functionalization and orthogonal assembly in this structure configuration can involve the same approach as outlined above for the two-terminal device. In some embodiments, many possible “wrong-bonded” arrangements, including for example if the two top nanoparticles adhere to the same source or drain contact, may be benign for device operation. Other trench designs can include an evaporated nanowire in the middle of the nanotrench to reduce parasitic capacitance due to the gate/source overlap. Charge transport measurements may be performed in these structures as a function of temperature and ambient. Results may be compared to results from scanning probe measurements performed as described below. Control and test structures fabricated on silicon may also be utilized to demonstrate and specify performance. These silicon-based test structures may demonstrate functional three-terminal molecular constructs that exhibit current and/or voltage gain.

A molecular assembly and alignment strategy according to some embodiments of the present invention also can enable electronic characterization of sets of molecular elements. Fabricated fan-out structures may be contacted by microprobes to enable measurement of current and capacitance vs. voltage, and analysis of charge transport parameters, including hole and electron mobility and conductivity mechanisms. Initial characterization of charge transport in molecules may be performed on two-terminal structures using scanning probe microscopy, where current is measured in or out of the Au contact through the substrate. Current vs. voltage may be characterized over a wide temperature range for several molecular elements. Specifically, the effect of (1) the length of the source and drain arms, (2) differences in the electrical characteristics when Pt/isonitrile and Au/thiol contacts are alternatively used and/or (3) control molecules (those where the gate moiety is removed) may be determined. Full-patterned contact approaches, as described above may also be fabricated. Detailed electronic characterization of the test structure and molecular elements may be performed, including characterization of test structure parasitic capacitance vs. frequency and voltage, and leakage current vs. voltage and temperature. Analysis of molecular capacitance-voltage and current-voltage characteristics may be compared for several molecular elements, and results may be analyzed in terms of theoretical expectations. This effort can further define and understand problems associated with charge transport though contacts and molecular structures, including two and three-terminal molecules, to build realistic molecular electronic circuits and system elements.

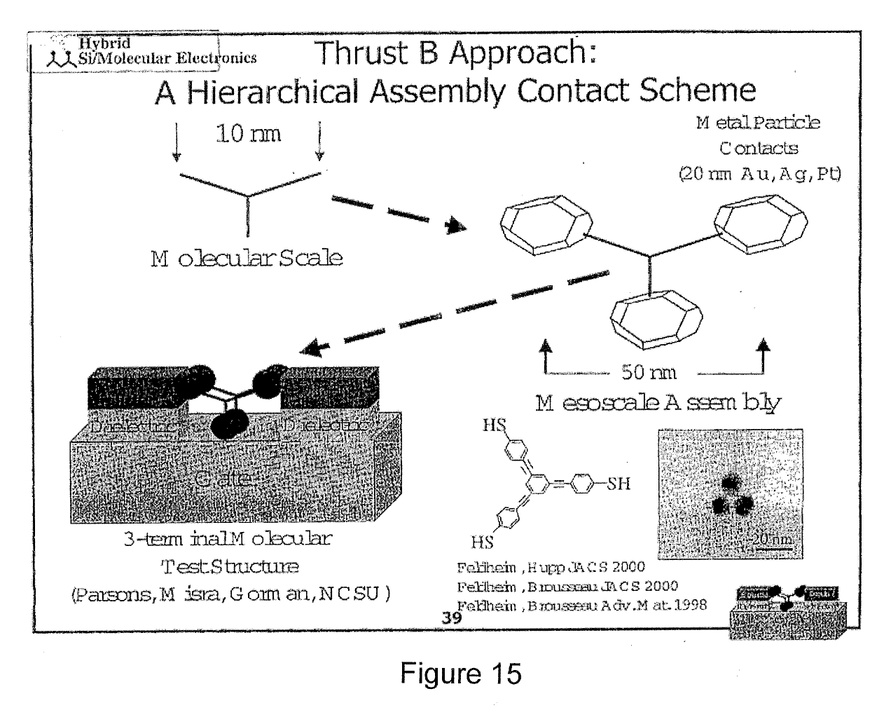

Accordingly, some embodiments of the present invention can provide nanopatterned structures that can enable nanoscale molecular assemblies to be aligned, so that independent electrical contact can be made to each terminal of a multi-terminal module. The nanoscale molecular assemblies can be, for example, hierarchically assembled nanoparticle/molecule hetero- and/or homo-structures, where each terminus of a molecule is selectively attached in an aqueous or non-aqueous environment to a functionalized and/or non-functionalized nanoparticle. The nanoparticle assembly may include a two or more terminal molecule, and a nanoscaled structure includes nanoscale trenches where the trenches expose two different conducting surfaces vertically separated by nanoscale insulating layers. By coupling the nanopattern trench structures with nanoparticle structures, fault tolerant molecular switching devices that enable voltage and/or current gain can be realized for very high density memory, sensing and/or logic devices that may be significantly more dense and faster than conventional silicon transistor technology. See FIG. 15.

An understanding of interfacial reactions and defects may be used to optimize device assembly, operation, and reliability. Spectroscopic chemical characterization may be performed of the interface between the patterned inorganic layers and the organic functionalized nanoparticles; and/or the interface between the nanoparticle and the electronically functional molecular element, to understand interfacial bonding to improve and advance the device assembly and operation. For example, understanding and optimizing bond selectivity between the functionalized nanoparticles and metal surfaces may allow improved fabrication and on-chip assembly of the three terminal molecular device structures described above.

A detailed understanding of the ligand exchange reaction, which takes place on gold particles, may also be obtained. NMR spectroscopic methodologies can characterize ligand exchange reactions on gold clusters in situ vs. temperature by synthesizing gold nanoclusters capped with ¹³C-labeled octanethiolate ligands (1-¹³C-octanethiol). The ¹³C label next to the thiol can enable the distinction between labeled thiol from unlabeled thiol including octanethiol, and/or the distinction of labeled thiol bound to gold clusters and labeled thiol in solution (Scheme 1). The latter is possible because the relaxation time of protons in close proximity to gold particles may be too fast to observe. Thus, as labeled thiols from solution adsorb onto the cluster, resonances due to the α protons may disappear. Isotopic labeling of any other carbon in the alkane or by any other chemical moiety (e.g., an end group)²⁹⁻³¹ may render the exchange products indistinguishable from reactants in situ. (Although the α proton resonances of an incoming thiol may still disappear, they may be replaced by those of the exiting ligand, Scheme 1).

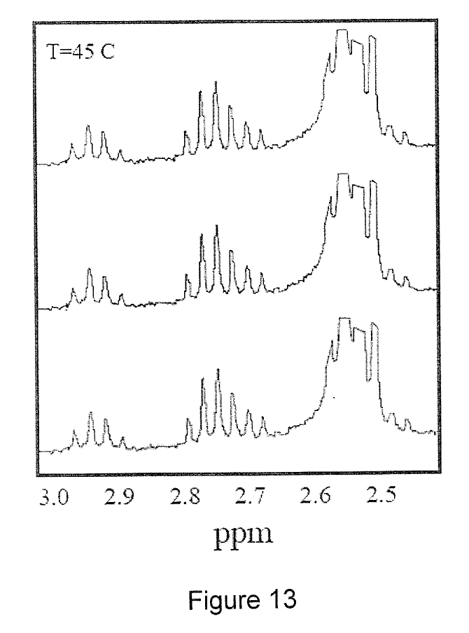

¹³C labeling the α carbon thus can allow ligand exchange dynamics to be monitored during self-exchanges (i.e., in the absence of a thermodynamic driving force), in the absence of end group effects, and/or in situ, without the need for separating solution-phase thiols from cluster-bound thiols. Sample NMR spectra for a self-exchange reaction on gold nanoclusters are shown in FIG. 13. Data of this type have revealed that (i) thiol self-exchange proceeds via both associative and dissociative mechanisms, (ii) at 25° C., shorter chain thiols in solution (C₆SH) may not replace longer chains bound to the cluster (C₁₂SH), and (iii) elevating the temperature slightly (40° C.) can enable short chain for long chain exchanges. Result (iii) may be noteworthy because techniques for isolating size monodisperse gold clusters may be particularly well developed when the capping ligand is C₈SH. Without knowledge of the temperature dependence of ligand exchange reactions, these size monodisperse clusters may only be available with thiol ligands longer than C₈.

The rates and mechanisms of ligand cross-reactions on gold and platinum nanoclusters may be characterized. That is, the rate and extent of substitution reactions in which a cluster-bound thiol is replaced by an isocyanide may be characterized. A detailed understanding of these exchange processes may be used to optimize the orthogonal chemical assembly schemes described herein.

Chemical characterization of inorganic/organic interfaces may also use surface spectroscopic tools, including X-ray photoelectron spectroscopy, angle resolved XPS, scanning Auger electron spectroscopy, and attenuated total reflection Fourier transform infrared absorption spectroscopy (ATR-FTIR). Questions that may be addressed include the effects of molecule/substrate interactions, molecular charge density, intermolecular packing forces and alignment and ordering of molecules on surfaces. Assembled functional organic linker molecules and nanoparticle assemblies may be characterized on various metal and insulator surfaces to: 1) determine adhesion density and selectivity, and adhesion reliability under post-adhesion processing; 2) utilize angle resolved XPS and other spectroscopic tools to characterize inorganic/organic bond structure, as well as alignment of organic linkers and nanoparticle assemblies on blanket and patterned inorganic surfaces; 3) examine effects of process contamination, including for example dry-etch residue, on adhesion and alignment of molecular linkers and functionalized nanoparticles; and/or 4) examine the role of metal deposition on the integrity of the molecules via XPS.

Surface spectroscopy tools may be used to chemically probe molecule/nanoparticle structures assembled in silicon test devices. First of all, molecular electronics may suffer from inadequate characterization of molecular species within a circuit. Moreover, the alignment and adhesion of molecule/nanoparticle structures may lead to structural changes in the active molecules that could affect their electrical activity and performance. Several of these techniques are “bulk” spectroscopic phenomena, so they may be performed on a large group of nanostructures embedded in an array of trenches or other lithographically patterned features. However, this type of characterization, while not at the single molecule level, may provide evidence that the assembly methodology retains signatures expected for the molecule/nanoparticle assemblies being inserted into the lithographically defined structures. Vibrational spectroscopy (surface-based Attenuated Total Reflection IR) may be used to confirm the chemical structure of the species inserted into the surface-based structure. Simple comparison of solution IR with surface IR may show this. X-ray photoelectron spectroscopy may also be used to look for molecular signatures (e.g., iron signals in ferrocenyl linkages, metal signatures in various porphyrin linkages), as well as bonding configurations and oxidation states of atoms in the structure. Signatures of trench-aligned molecules (confirmed by AFM or STM) could be compared to “free” adsorbed layers on planar surfaces. Careful experimental design may be needed to perform detailed studies, but any such insight may be broadly applicable to understanding the role of confinement and geometry modification on electronic structure and properties of organized molecular systems.

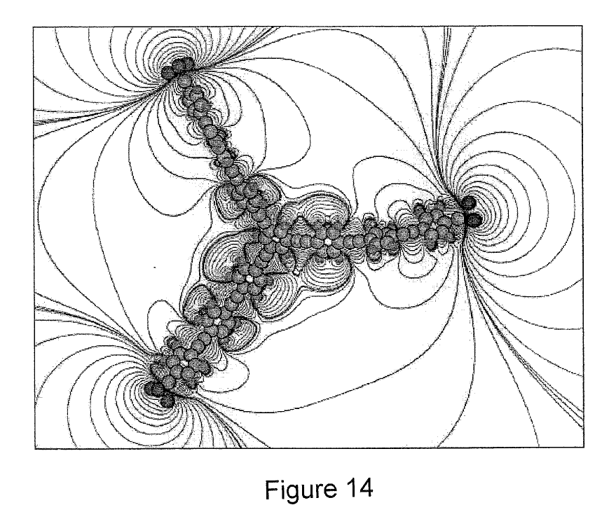

Modeling of transport properties of molecular assemblies may be somewhat premature until assembly to bridge lithographic and molecular length scales is better developed. An example of a molecular orbital calculation performed on a proposed trimer is shown in FIG. 14.

Accordingly, embodiments of the invention can provide engineered structures that enable characterization and utilization of electronic transport in multi-terminal synthesized molecules. Room temperature orthogonal self-assembly can be used to hierarchically assemble molecule-based devices. This type of hierarchical self-assembly is potentially scalable to fabrication of large arrays of nanoelements and to spectroscopic and electrical characterization of the assembled structures, including demonstration of gain due to a redox event. These structures can enable improved understanding of how chemical structure (e.g., bond and ligand configuration) is linked to basic electronic properties and function, including charge transport mechanisms, molecular/metal electronic coupling and contact resistance, transport threshold fields, and charge mobility. Moreover, understanding the kinetics and thermodynamics of ligand exchange may enable the orthogonal assembly of 3-terminal molecule/nanoparticle heterostructures.

In the drawings and specification, there have been disclosed embodiments of the invention and, although specific terms are employed, they are used in a generic and descriptive sense only and not for purposes of limitation, the scope of the invention being set forth in the following claims.

### REFERENCES

(1) Joachim, C.; Gimzewski, J. K. “A nanoscale single-molecule amplifier and its consequences”, Proc. IEEE 1998, 86, 184-190.
(2) Cui, Y.; Lieber, C. M. “Functional nanoscale electronic devices assembled using silicon nanowire building blocks”, Science 2001, 291, 851-853.
(3) Liang, W. J.; Shores, M. P.; Bockrath, M.; Long, J. R.; Park, H. “Kondo resonance in a single-molecule transistor”, Nature 2002, 417, 725-729.
(4) Park, J.; Pasupathy, A. N.; Goldsmith, J. L.; Chang, C.; Yaish, Y.; Petta, J. R.; Rinkoski, M.; Sethna, J. P.; Abruña, H. D.; McEuen, P. L.; Ralph, D. C. “Coulomb blockade and the Kondo effect in single-atom transistors”, Nature 2002, 417, 722-725.
(5) Tour, J. M. “Molecular electronics. Synthesis and testing of components”, Accounts Chem. Res. 2000, 33, 791-804.
(6) Wada, Y. “A prospect for single molecule information processing devices”, Pure Appl. Chem. 1999, 71, 2055-2066.
(7) Wada, Y. “Proposal of atom/molecule switching devices”, J. Vac. Sci. Technol. A—Vac. Surf. Films 1999, 17, 1399-1405.
(8) Novak, J. P.; Nickerson, C.; Franzen, S.; Feldheim, D. L. “Purification of Molecularly Bridged Nanoparticle Arrays by Centrifugation and Size-exclusion Chromatography”, Anal. Chem. 2001, 73, 5758-5761.
(9) Novak, J. P.; Feldheim, D. L. “Assembly of Phenylacetylene-bridged Gold and Silver Nanoparticle Arrays”, J. Am. Chem. Soc. 2000, 122, 3979.
(10) Brousseau III, L. C.; Novak, J. P.; Marinakos, S. M.; Feldheim, D. L. “Assembly of Phenylacetylene-bridged Gold Nanocluster Dimers and Trimers”, Adv. Mater. 1999, 11, 447.
(11) Novak, J. P.; Brousseau III, L. C.; Vance, F. W.; Lemon, B. I.; Johnson, R. C.; Hupp, J. T.; Feldheim, D. L. “Nonlinear Optical Properties of Molecularly Bridged Gold Nanoparticle Arrays”, J. Am. Chem. Soc. 2000, 122, 12029-12030.
(12) Jiang, J.; Novak, J. P.; Feldheim, D. L.; Brus, L., Unpublished Data.
(13) Hickman, J. J.; Laibinis, P. E.; Auerbach, D. I.; Zou, C.; Gardner, T. J.; Whitesides, G. M.; Wrighton, M. S. “Toward orthogonal self-assembly of redox active molecules on Pt and Au: Selective reaction of disulfide with Au and isocyanide with Pt”, Langmuir 1992, 8, 357-359.
(14) Laibinis, P. E.; Hickman, J. J.; Wrighton, M. S.; Whitesides, G. M. “Orthogonal self-assembled monolayers: Alkanethiols on gold and alkane carboxylic acids on alumina”, Science 1989, 245, 845-847.
(15) In this work, it was shown that isonitriles and thiols could orthogonally self-assemble on segmented gold/platinum/gold nanowires: Mbindyo, J. K. N.; Reiss, B. D.; Martin, B. R.; Keating, C. D.; Natan, M. J.; Mallouk, T. E. “DNA-directed assembly of gold nanowires on complementary surfaces”, Adv. Mater. 2001, 13, 249-254.
(16) Heimer, T. A.; Darcangelis, S. T.; Farzad, F.; Stipkala, J. M.; Meyer, G. J. “An acetylacetonate-based semiconductor-sensitizer linkage”, Inorg. Chem. 1996, 35, 5319-5324.
(17) Cao, F.; Oskam, G.; Searson, P. C.; Stipkala, J. M.; Heimer, T. A.; Farzad, F.; Meyer, G. J. “Electrical and Optical-Properties of Porous Nanocrystalline TiO₂ Films”, J. Phys. Chem. 1995, 99, 11974-11980.
(18) Argazzi, R.; Bignozzi, C. A.; Heimer, T. A.; Castellano, F. N.; Meyer, G. J. “Enhanced Spectral Sensitivity from Ruthenium(Ii) Polypyridyl Based Photovoltaic Devices”, Inorg. Chem. 1994, 33, 5741-5749.
(19) Beek, W. J. E.; Janssen, R. A. J. “Photoinduced electron transfer in heterosupramolecular assemblies of TiO2 nanoparticles and terthiophene carboxylic acid in apolar solvents”, Adv. Funct. Mater. 2002, 12, 519-525.
(20) Henderson, J. I.; Feng, S.; Bein, T.; Kubiak, C. P. “Adsorption of diisocyanides on gold”, Langmuir 2000, 16, 6183-6187.
(21) Xu, Z.; Kahr, M.; Walker, K. L.; Wilkins, C. L.; Moore, J. S. “Phenylacetylene Dendrimers by the Divergent, Convergent, and Double-Stage Convergent Methods”, J. Am. Chem. Soc. 1994, 116, 4537-4550.
(22) Tour, J. M.; II, L. J.; Pearson, D. L.; Lamba, J. J. S.; Burgin, T. P.; Whitesides, G. M.; Allara, D. L.; Parikh, A. N.; Atre, S. V. “Self-Assembled Monolayers and Multilayers of Conjugated Thiols, α,ω-Dithiols, and Thioacetyl-Containing Adsorbates. Understanding Attachments between Potential Molecular Wires and Gold Surfaces”, J. Am. Chem. Soc. 1995, 117, 9529-9534.
(23) Yang, C. S.; Smith, L. L.; Arthur, C. B.; Parsons, G. N. “Stability of low-temperature amorphous silicon thin film transistors formed on glass and transparent plastic substrates”, J. Vac. Sci. Technol. B 2000, 18, 683-689.
(24) Sieval, A. B.; Linke, R.; Heij, G.; Meijer, G.; Zuilhof, H.; Sudholter, E. J. R. “Amino-terminated organic monolayers on hydrogen-terminated silicon surfaces”, Langmuir 2001, 17, 7554-7559.
(25) Buriak, J. M.; Stewart, M. P.; Geders, T. W.; Allen, M. J.; Choi, H. C.; Smith, J.; Raftery, D.; Canham, L. T. “Lewis acid mediated hydrosilylation on porous silicon surfaces”, J. Am. Chem. Soc. 1999, 121, 11491-11502.
(26) Buriak, J. M. “Silicon-carbon bonds on porous silicon surfaces”, Adv. Mater. 1999, 11, 265-267.
(27) Stewart, M. P.; Buriak, J. M. “Photopatterned hydrosilylation on porous silicon”, Angew. Chem.—Int. Edit. 1998, 37, 3257-3260.
(28) Buriak, J. M.; Allen, M. J. “Lewis acid mediated functionalization of porous silicon with substituted alkenes and alkynes”, J. Am. Chem. Soc. 1998, 120, 1339-1340.
(29) Templeton, A. C.; Hostetler, M. J.; Warmoth, E. K.; Chen, S. W.; Hartshorn, C. M.; Krishnamurthy, V. M.; Forbes, M. D. E.; Murray, R. W. “Gateway reactions to diverse, polyfunctional monolayer-protected gold clusters”, J. Am. Chem. Soc. 1998, 120, 4845-4849.
(30) Templeton, A. C.; Hostetler, M. J.; Kraft, C. T.; Murray, R. W. “Reactivity of monolayer-protected gold cluster molecules: Steric effects”, J. Am. Chem. Soc. 1998, 120, 1906-1911.
(31) Ingram, R. S.; Hostetler, M. J.; Murray, R. W. “Poly-hetero-omega-functionalized alkanethiolate-stabilized gold cluster compounds”, J. Am. Chem. Soc. 1997, 119, 9175-9178.
(32) Fuierer, R. R.; Carroll, R. L.; Feldheim, D. L.; Gorman, C. B. “Patterning Mesoscale Gradient Structures with Self-Assembled Monolayers and Scanning Tunneling Microscopy Based Replacement Lithography”, Adv. Mater. 2001, 154-157.

What is claimed is:

1. A nanostructure comprising:
a substrate having a trench therein, including a conductive trench floor and first and second conductive contacts at a trench opening that are spaced apart from the trench floor; and
a molecularly bridged nanoparticle in the trench that is electrically connected between the first and second conductive contacts at the trench opening and the conductive trench floor.

2. A method of fabricating a nanostructure comprising:
forming a substrate having a trench therein, including a conductive trench floor and first and second conductive contacts at a trench opening that are spaced apart from the trench floor; and
placing a molecularly bridged nanoparticle in the trench such that the molecularly bridged nanoparticle is electrically connected between the first and second conductive contacts at the trench opening and the conductive trench floor.
